(19) United States
(12) Patent Application Publication
(10) Pub. No.: US 2025/0208526 A1
(43) Pub. Date: Jun. 26, 2025

(54) PHOTOLITHOGRAPHY SUBSTRATE WITH PURGE FLOW DIRECTION

(71) Applicant: ENTEGRIS, INC., Billerica, MA (US)

(72) Inventors: Huaping Wang, Eden Prairie, MN (US); Caleb Elwell, Manitou Springs, CO (US); Russ V. Raschke, Chanhassen, MN (US)

(21) Appl. No.: 18/989,856

(22) Filed: Dec. 20, 2024

Related U.S. Application Data
(60) Provisional application No. 63/614,868, filed on Dec. 26, 2023.

(51) Int. Cl. G03F 7/00

(52) U.S. Cl. CPC G03F 7/70933; G03F 7/70808

(57) ABSTRACT

A photolithography substrate container includes an inlet configured to receive purge gas, baffles, a photolithography substrate accommodation space, and an outlet for the purge gas. The baffles can affect the flow of purge gas received at the inlet to control flow rates, pressure differentials, and the like for the flow of purge gas through the photolithography substrate accommodation space. The baffles can be provided between the inlet and the photolithography substrate accommodation space. The baffles can be included on one or more parts of the photolithography substrate container or on an insert configured to be attached thereto.

### FIELD

This disclosure is directed to containers for photolithography substrates including features for receiving and directing a purge flow.

### BACKGROUND

Photolithography components can be expensive and delicate. Reticles can be sensitive to contaminants or damage from particulate matter. Pellicles can also be sensitive to contaminants and particulate, and further are vulnerable to physical disruptions, such as large pressure differentials across the pellicle.

### SUMMARY

This disclosure is directed to containers for photolithography substrates including features for receiving and directing a purge flow.

By allowing a purge flow to be provided, substrate containers can allow contaminants such as humidity, volatile organic compounds (VOCs), or the like to be driven from the space containing the substrate. This can reduce or prevent the effects of contaminants on the photolithography substrates, therefore improving the lifetime and providing cost and materials savings. By providing features to direct and distribute the purge flow within the container, the effectiveness of the purge flow can be increased, and the risk of damage, for example due to uneven flow, excessive flow rates, pressure differentials across the photolithography substrate, or the like.

In an embodiment, a photolithography substrate container includes a first shell portion, a purge inlet, a purge outlet, and a second shell portion. The first shell portion and the second shell portion define a photolithography substrate accommodation space configured to receive a photolithography substrate. The photolithography substrate container further includes a plurality of baffles configured to be positioned between the purge inlet and the photolithography substrate accommodation space when the first shell portion and the second shell portion are closed together.

In an embodiment, at least some of the plurality of baffles are formed integrally with the first shell portion. In an embodiment, at least some of the plurality of baffles are formed integrally with the second shell portion. In an embodiment, at least some of the plurality of baffles are provided in an insert configured to be joined to at least one of the first shell portion and the second shell portion. In an embodiment, the plurality of baffles are provided in a plurality of rows. In an embodiment, the plurality of baffles are arranged in a single row. In an embodiment, at least some baffles of the plurality of baffles have a rectangular profile. In an embodiment, at least some baffles of the plurality of baffles have a trapezoidal profile.

In an embodiment, a pellicle container includes a first shell portion, a purge inlet, a purge outlet, and a second shell portion. The first shell portion and the second shell portion define a pellicle accommodation space configured to receive a pellicle. The pellicle container further includes a plurality of baffles configured to be positioned between the purge inlet and the pellicle accommodation space when the first shell portion and the second shell portion are closed together.

In an embodiment, at least some of the plurality of baffles are formed integrally with the first shell portion. In an embodiment, at least some of the plurality of baffles are formed integrally with the second shell portion. In an embodiment, at least some of the plurality of baffles are provided in an insert configured to be joined to at least one of the first shell portion and the second shell portion. In an embodiment, the plurality of baffles are provided in a plurality of rows. In an embodiment, the plurality of baffles are arranged in a single row. In an embodiment, at least some baffles of the plurality of baffles have a rectangular profile. In an embodiment, at least some baffles of the plurality of baffles have a trapezoidal profile.

In an embodiment, a method of purging a pellicle container includes receiving a flow of a purge gas at a purge inlet of the pellicle container, directing the purge gas through a plurality of baffles into a pellicle accommodation space of the pellicle container, and directing the purge gas out of the pellicle container through a purge gas outlet of the pellicle container.

In an embodiment, the method further includes attaching an insert including at least some of the plurality of baffles into the pellicle container. In an embodiment, the method further includes placing a pellicle into the pellicle accommodation space. In an embodiment, the method further includes cleaning the pellicle container using water and drying the pellicle container after the cleaning.

### DRAWINGS

FIG. 1 shows a photolithography substrate container according to an embodiment.

FIG. 2 shows a photolithography substrate container according to an embodiment.

FIG. 3 shows a photolithography substrate container according to an embodiment.

FIG. 4A shows a plurality of baffles according to an embodiment.

FIG. 4B shows a plurality of baffles according to an embodiment.

FIG. 5A shows a portion of a photolithography substrate container according to an embodiment.

FIG. 5B shows a portion of a photolithography substrate container according to an embodiment.

### DETAILED DESCRIPTION

This disclosure is directed to containers for photolithography substrates including features for receiving and directing a purge flow.

As used herein, “photolithography substrate” refers to a substrate used in a photolithography process, such as a reticle, a pellicle, or a combination thereof.

As used herein, “photolithography substrate container” refers to a container configured to accommodate a photolithography substrate, such as a pellicle container, a reticle container, or the like.

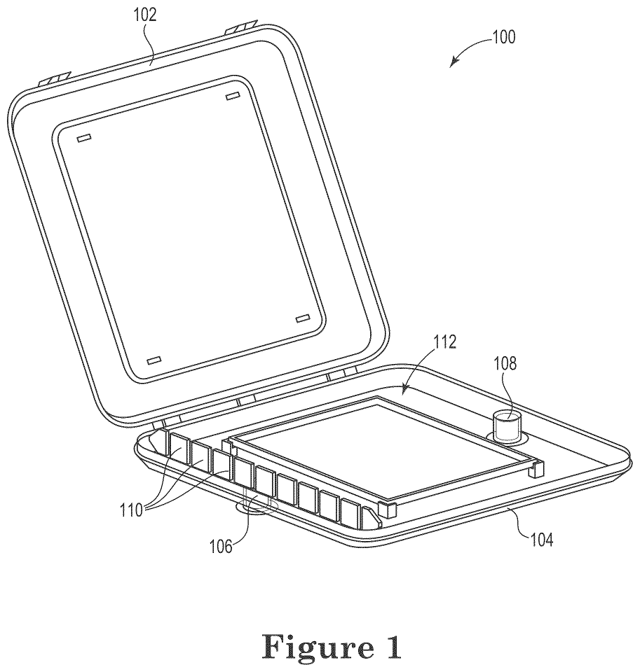

FIG. 1 shows a photolithography substrate container according to an embodiment. Photolithography substrate container 100 includes first shell portion 102 and second shell portion 104. The photolithography substrate container further includes a purge inlet 106, a purge outlet 108, and a plurality of baffles 110. The photolithography substrate container 100 defines a photolithography substrate accommodation space 112.

Photolithography substrate container 100 is a container configured to accommodate a photolithography substrate, such as, for example, a pellicle, a reticle, a combination thereof, or the like. In an embodiment, photolithography substrate container 100 is a pellicle container, such as a pellicle shipping container. In an embodiment, photolithography substrate container 100 is a reticle container, such as an extreme ultraviolet (EUV) reticle pod.

First shell portion 102 is a portion of photolithography substrate container 100 partially defining the internal space of photolithography substrate container 100. First shell portion 102 can be, for example, one piece of a pellicle container such as one clamshell portion thereof, a cover of a reticle pod, a pod dome of a reticle pod, or any other suitable portion of a photolithography substrate container.

Second shell portion 104 is another portion of photolithography substrate container 100 configured to be combined with the first shell portion 102 to form at least a portion of the photolithography substrate container 102. Second shell portion 104 can be, for example, one piece of a pellicle container such as another clamshell portion thereof, a baseplate of a reticle pod, a pod door of a reticle pod, or any other suitable portion of a photolithography substrate container.

Purge inlet 106 is an inlet allowing introduction of a purge gas into the interior space of photolithography substrate container 100. Purge inlet 106 can be any suitable structure configured to allow the introduction of the purge gas, such as an opening, a port, an interface, or the like. The purge inlet can be provided on at least one of first shell portion 102 and/or second shell portion 104. In embodiments, the purge inlet 106 can include any suitable structures for controlling, regulating, filtering, or otherwise modifying the flow passing through purge inlet 106, for example, valves, check valves, filters, or the like. The purge gas received at purge inlet 106 can be any suitable gas for purging the interior space of photolithography substrate container, such as clean dry air (CDA), extra clean dry air (XCDA), nitrogen, inert gases, or the like. The purge inlet 106 can be positioned such that the purge inlet 106 is outside of the photolithography substrate accommodation space 112. The purge inlet 106 can be positioned such that the purge inlet 106 is separated from the photolithography substrate accommodation space 112 by the plurality of baffles 110.

Purge outlet 108 is an outlet allowing the purge gas to exit the interior space of photolithography substrate container 100. Purge outlet 108 can be any suitable structure configures to allow the exit of the purge gas, such as an opening, a port, an interface, or the like. The purge outlet 108 can be provided on at least one of first shell portion 102 and/or second shell portion 104. In an embodiment, purge outlet 108 is on the same one of first shell portion 102 or second shell portion 104 that the purge inlet 106 is provided on. In an embodiment, purge outlet 108 is on an opposite one of first shell portion 102 or second shell portion 104 than purge inlet 106. The purge outlet 108 can include any suitable structures for controlling, regulating, or otherwise modifying the flow passing out of the photolithography substrate container 100 through purge outlet 108, for example, valves, check valves, or the like. The purge outlet 108 can be positioned such that the purge outlet 108 is outside the photolithography substrate accommodation space 112. In an embodiment, purge outlet 108 can be on an opposite side of the photolithography substrate accommodation space 112 from the purge inlet 106, such that a photolithography substrate within the photolithography substrate accommodation space would be disposed between the purge inlet 106 and the purge outlet 108.

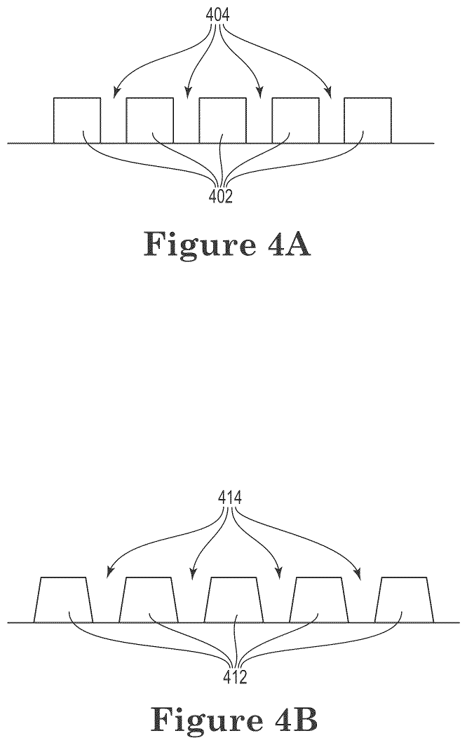

Baffles 110 each extend from the second shell portion 104 as shown in FIG. 1. In an alternative embodiment, each of baffles 110 can instead extend from first shell portion 102. Baffles 110 are any suitable baffles configured to direct, deflect, regulate, or otherwise affect the flow of purge gas from the purge inlet 106 so as to achieve desired flow characteristics in the photolithography substrate accommodation space 112. Baffles 110 can be provided in one or more rows extending across the interior space of the photolithography substrate container 100. The baffles 110 can have any suitable profile, such as being rectangular or trapezoidal in a front view as shown in FIGS. 4A and 4B and described below. The baffles 110 can be curved or planar. The baffles 110 can be generally perpendicular or angled with respect to a flow direction of purge gas from purge inlet 106 to purge outlet 108. The baffles 110 can have any suitable spacing to achieve the desired flow characteristics, such as being evenly spaced, having differing sizes of gaps between adjacent baffles based on the position of said adjacent baffles, or the like. The spacing of baffles 110 can further be based on an ability to dry the photolithography substrate container 100 following washing thereof, for example by having gaps of at least one eighth (⅛) of an inch between adjacent baffles 110.

Photolithography substrate accommodation space 112 is a portion of an interior space of the photolithography substrate container 100 configured to contain at least one photolithography substrate, such as a reticle, a pellicle, a combination thereof, or the like. The photolithography substrate accommodation space 112 is a continuous space sized to accommodate the at least one photolithography substrate and configured such that no components of photolithography substrate container 100 would interfere with the photolithography substrate when the photolithography substrate is within the photolithography substrate accommodation space 112. In an embodiment, the photolithography substrate accommodation space 112 is defined on one side by the plurality of baffles 110. In an embodiment, the photolithography substrate accommodation space 112 is on an opposite side of the plurality of baffles 110 from the purge inlet 106. In an embodiment, the photolithography substrate accommodation space 112 is positioned between the plurality of baffles 110 and the purge outlet 108. In an embodiment, the photolithography substrate accommodation space 112 includes one or more suitable supports or retainers for supporting and/or retaining the photolithography substrate within the photolithography substrate accommodation space 112.

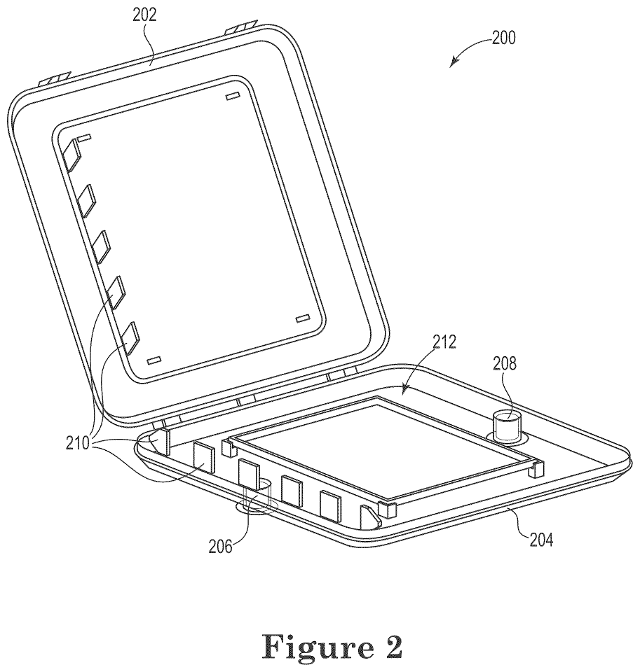

FIG. 2 shows a photolithography substrate container according to an embodiment. Photolithography substrate container 200 includes first shell portion 202 and second shell portion 204. The photolithography substrate container further includes a purge inlet 206, a purge outlet 208, and a plurality of baffles 220. The photolithography substrate container 200 defines a photolithography substrate accommodation space 212.

Photolithography substrate container 200 is a container configured to accommodate a photolithography substrate, such as, for example, a pellicle, a reticle, a combination thereof, or the like. In an embodiment, photolithography substrate container 200 is a pellicle container, such as a pellicle shipping container. In an embodiment, photolithography substrate container 200 is a reticle container, such as an extreme ultraviolet (EUV) reticle pod.

First shell portion 202 is a portion of photolithography substrate container 100 partially defining the internal space of photolithography substrate container 100. First shell portion 102 can be, for example, one piece of a pellicle container such as one clamshell portion thereof, a cover of a reticle pod, a pod dome of a reticle pod, or any other suitable portion of a photolithography substrate container.

Second shell portion 204 is another portion of photolithography substrate container 200 configured to be combined with the first shell portion 202 to form at least a portion of the photolithography substrate container 202. Second shell portion 204 can be, for example, one piece of a pellicle container such as another clamshell portion thereof, a baseplate of a reticle pod, a pod door of a reticle pod, or any other suitable portion of a photolithography substrate container.

Purge inlet 206 is an inlet allowing introduction of a purge gas into the interior space of photolithography substrate container 200. Purge inlet 206 can be any suitable structure configured to allow the introduction of the purge gas, such as an opening, a port, an interface, or the like. The purge inlet can be provided on at least one of first shell portion 202 and/or second shell portion 204. In embodiments, the purge inlet 206 can include any suitable structures for controlling, regulating, filtering, or otherwise modifying the flow passing through purge inlet 206, for example, valves, check valves, filters, or the like. The purge gas received at purge inlet 206 can be any suitable gas for purging the interior space of photolithography substrate container, such as clean dry air (CDA), extra clean dry air (XCDA), nitrogen, inert gases, or the like. The purge inlet 206 can be positioned such that the purge inlet 206 is outside of the photolithography substrate accommodation space 212. The purge inlet 206 can be positioned such that the purge inlet 206 is separated from the photolithography substrate accommodation space 212 by the plurality of baffles 210.

Purge outlet 208 is an outlet allowing the purge gas to exit the interior space of photolithography substrate container 200. Purge outlet 208 can be any suitable structure configures to allow the exit of the purge gas, such as an opening, a port, an interface, or the like. The purge outlet 208 can be provided on at least one of first shell portion 202 and/or second shell portion 204. In an embodiment, purge outlet 208 is on the same one of first shell portion 202 or second shell portion 204 that the purge inlet 206 is provided on. In an embodiment, purge outlet 208 is on an opposite one of first shell portion 202 or second shell portion 204 than purge inlet 206. The purge outlet 208 can include any suitable structures for controlling, regulating, or otherwise modifying the flow passing out of the photolithography substrate container 200 through purge outlet 208, for example, valves, check valves, or the like. The purge outlet 208 can be positioned such that the purge outlet 208 is outside the photolithography substrate accommodation space 212. In an embodiment, purge outlet 208 can be on an opposite side of the photolithography substrate accommodation space 212 from the purge inlet 206, such that a photolithography substrate within the photolithography substrate accommodation space would be disposed between the purge inlet 206 and the purge outlet 208.

Baffles 210 are provided on both of first shell portion 202 and second shell portion 204, with some of baffles 210 extending from first shell portion 202 and other baffles 210 extending from second shell portion 204 in the embodiment shown in FIG. 2. The baffles 210 can be provided on The baffles 210 are any suitable baffles configured to direct, deflect, regulate, or otherwise affect the flow of purge gas from the purge inlet 206 so as to achieve desired flow characteristics in the photolithography substrate accommodation space 212. Baffles 210 can be provided in one or more rows extending across the interior space of the photolithography substrate container 200. The baffles 210 can have any suitable profile, such as being rectangular or trapezoidal in a front view as shown in FIGS. 4A and 4B and described below. The baffles 210 can be curved or planar. The baffles 210 can be generally perpendicular or angled with respect to a flow direction of purge gas from purge inlet 206 to purge outlet 208. The baffles 210 can have any suitable spacing to achieve the desired flow characteristics, such as being evenly spaced, having differing sizes of gaps between adjacent baffles based on the position of said adjacent baffles, or the like. The spacing of baffles 210 provided on the same of first shell portion 202 or second shell portion 204 can further be based on an ability to dry the photolithography substrate container following washing thereof, for example by having gaps of at least one eighth (⅛) of an inch between baffles that are provided on one of the first shell portion 202 or the second shell portion 204. It is understood that baffles 210 can alternate projecting from the first shell portion 202 and the second shell portion 204, allowing a larger gap to be present between baffles that are adjacent on one of first shell portion 202 or second shell portion 204 when the container is opened for drying compared to the size of the gaps between baffles that are adjacent when the first shell portion 202 and the second shell portion 204 are closed together.

Photolithography substrate accommodation space 212 is a portion of an interior space of the photolithography substrate container 200 configured to contain at least one photolithography substrate, such as a reticle, a pellicle, a combination thereof, or the like. The photolithography substrate accommodation space 212 is a continuous space sized to accommodate the at least one photolithography substrate and configured such that no components of photolithography substrate container 200 would interfere with the photolithography substrate when the photolithography substrate is within the photolithography substrate accommodation space 212. In an embodiment, the photolithography substrate accommodation space 212 is defined on one side by the plurality of baffles 210. In an embodiment, the photolithography substrate accommodation space 212 is on an opposite side of the plurality of baffles 210 from the purge inlet 206. In an embodiment, the photolithography substrate accommodation space 212 is positioned between the plurality of baffles 210 and the purge outlet 108. In an embodiment, the photolithography substrate accommodation space 212 includes one or more suitable supports or retainers for supporting and/or retaining the photolithography substrate within the photolithography substrate accommodation space 212.

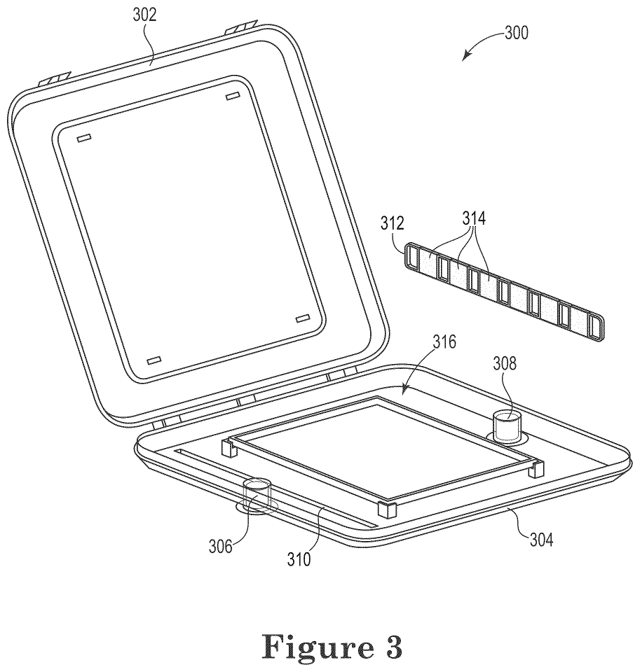

FIG. 3 shows a photolithography substrate container according to an embodiment. Photolithography substrate container 300 includes first shell portion 302 and second shell portion 304. The photolithography substrate container further includes a purge inlet 306, a purge outlet 308, and an insert interface 310. Photolithography substrate container 300 further includes insert 312, the insert 312 including a plurality of baffles 314. The photolithography substrate container 300 defines a photolithography substrate accommodation space 316.

Photolithography substrate container 300 is a container configured to accommodate a photolithography substrate, such as, for example, a pellicle, a reticle, a combination thereof, or the like. In an embodiment, photolithography substrate container 300 is a pellicle container, such as a pellicle shipping container. In an embodiment, photolithography substrate container 300 is a reticle container, such as an extreme ultraviolet (EUV) reticle pod.

First shell portion 302 is a portion of photolithography substrate container 100 partially defining the internal space of photolithography substrate container 100. First shell portion 102 can be, for example, one piece of a pellicle container such as one clamshell portion thereof, a cover of a reticle pod, a pod dome of a reticle pod, or any other suitable portion of a photolithography substrate container.

Second shell portion 304 is another portion of photolithography substrate container 300 configured to be combined with the first shell portion 302 to form at least a portion of the photolithography substrate container 302. Second shell portion 304 can be, for example, one piece of a pellicle container such as another clamshell portion thereof, a baseplate of a reticle pod, a pod door of a reticle pod, or any other suitable portion of a photolithography substrate container.

Purge inlet 306 is an inlet allowing introduction of a purge gas into the interior space of photolithography substrate container 300. Purge inlet 306 can be any suitable structure configured to allow the introduction of the purge gas, such as an opening, a port, an interface, or the like. The purge inlet can be provided on at least one of first shell portion 302 and/or second shell portion 304. In embodiments, the purge inlet 306 can include any suitable structures for controlling, regulating, filtering, or otherwise modifying the flow passing through purge inlet 306, for example, valves, check valves, filters, or the like. The purge gas received at purge inlet 306 can be any suitable gas for purging the interior space of photolithography substrate container, such as clean dry air (CDA), extra clean dry air (XCDA), nitrogen, inert gases, or the like. The purge inlet 306 can be positioned such that the purge inlet 306 is outside of the photolithography substrate accommodation space 312. The purge inlet 306 can be positioned such that the purge inlet 306 is separated from the photolithography substrate accommodation space 312 by the plurality of baffles 310.

Purge outlet 308 is an outlet allowing the purge gas to exit the interior space of photolithography substrate container 300. Purge outlet 308 can be any suitable structure configures to allow the exit of the purge gas, such as an opening, a port, an interface, or the like. The purge outlet 308 can be provided on at least one of first shell portion 302 and/or second shell portion 304. In an embodiment, purge outlet 308 is on the same one of first shell portion 302 or second shell portion 304 that the purge inlet 306 is provided on. In an embodiment, purge outlet 308 is on an opposite one of first shell portion 302 or second shell portion 304 than purge inlet 306. The purge outlet 308 can include any suitable structures for controlling, regulating, or otherwise modifying the flow passing out of the photolithography substrate container 300 through purge outlet 308, for example, valves, check valves, or the like. The purge outlet 308 can be positioned such that the purge outlet 308 is outside the photolithography substrate accommodation space 312. In an embodiment, purge outlet 308 can be on an opposite side of the photolithography substrate accommodation space 316 from the purge inlet 306, such that a photolithography substrate within the photolithography substrate accommodation space would be disposed between the purge inlet 306 and the purge outlet 308.

Insert interface 310 is a feature formed on one or both of the first shell portion 302 and/or second shell portion 304 configured to retain an insert 312. The insert interface can be any suitable mechanical interface capable of allowing attachment of the insert 312, for example one or more grooves, channels, or other recesses configured to receive one or more portions of insert 312, slots, tabs, posts, or other projections configured to be received by insert 312, or the like.

Insert 312 is configured to be secured to first shell portion 302 and/or second shell portion 304 such that photolithography substrate container 300 can be closed containing insert 312. Insert 312 can include any suitable features for attaching to the photolithography substrate container 300 at insert interface 310. Insert 312 can include, for example, one or more projections such as slots, tabs, posts, or the like configured to be received in groove, channel, or other recess provided in insert interface 310, or one or more suitable grooves, channels, or other recesses configured to receive projections provided on insert interface 310. Insert 312 is configured to provide baffles 314 within the photolithography substrate container 300, for example between purge inlet 306 and photolithography substrate accommodation space 316.

Baffles 314 are included in insert 312 in the embodiment shown in FIG. 3. Baffles 314 are any suitable baffles configured to direct, deflect, regulate, or otherwise affect the flow of purge gas from the purge inlet 306 so as to achieve desired flow characteristics in the photolithography substrate accommodation space 316. Baffles 314 can be provided in one or more rows extending across the interior space of the photolithography substrate container 300. The baffles 314 can have any suitable profile, such as being rectangular or trapezoidal in a front view as shown in FIGS. 4A and 4B and described below. The baffles 314 can be curved or planar. The baffles 314 can be generally perpendicular or angled with respect to a flow direction of purge gas from purge inlet 306 to purge outlet 308. The baffles 314 can have any suitable spacing to achieve the desired flow characteristics, such as being evenly spaced, having differing sizes of gaps between adjacent baffles based on the position of said adjacent baffles, or the like. The spacing of baffles 314 can further be based on an ability to dry the insert 312 following washing thereof, for example by having gaps of at least one eighth (⅛) of an inch between adjacent baffles 314.

Photolithography substrate accommodation space 316 is a portion of an interior space of the photolithography substrate container 300 configured to contain at least one photolithography substrate, such as a reticle, a pellicle, a combination thereof, or the like. The photolithography substrate accommodation space 316 is a continuous space sized to accommodate the at least one photolithography substrate and configured such that no components of photolithography substrate container 300 would interfere with the photolithography substrate when the photolithography substrate is within the photolithography substrate accommodation space 316. In an embodiment, the photolithography substrate accommodation space 316 is defined on one side by insert interface 310 and/or insert 312 when insert 312 is attached to photolithography substrate container 300. In an embodiment, the photolithography substrate accommodation space 316 is on an opposite side of the plurality of baffles 314 from the purge inlet 306. In an embodiment, the photolithography substrate accommodation space 316 is positioned between the plurality of baffles 314 and the purge outlet 308. In an embodiment, the photolithography substrate accommodation space 316 includes one or more suitable supports or retainers for supporting and/or retaining the photolithography substrate within the photolithography substrate accommodation space 316.

FIG. 4A shows a plurality of baffles according to an embodiment. In FIG. 4A, a front view of the plurality of baffles is provided. Each of the baffles 402 has a rectangular profile, i.e. is rectangular in shape when viewed in the front view shown in FIG. 4A. A gap 404 is provided between each of the baffles 402 shown in FIG. 4A. The gap 404 can have a consistent width along the height thereof. In an embodiment, the gap 404 is sized so as to promote drying of the container including the baffles 402 following washing, for example by having the gaps 404 each being at least one eighth of an inch (⅛″) in width. In an embodiment, this spacing of the gaps is provided when all of the baffles 402 extend from the same container shell portion. In an embodiment where baffles 402 alternate extending from opposing container shell portions (for example, as described above and shown in FIG. 2), the gaps 404 between adjacent baffles 402 when the container is closed can be sized without respect to water trapping effects. For example, the gaps 404 between baffles 402 when the container is closed can be smaller than one eighth of an inch (⅛″) in width. The width of the gaps 404 can be selected based on the desired flow characteristics within a container including the baffles 402. In an embodiment, the width of the gaps 404 can be varied along a length of a row of the baffles 402, for example varying based on a distance of the particular baffle 402 from a center line of the container, distance from a purge inlet, or any other suitable basis for selecting the sizing of gaps 404 so as to achieve desired flow conditions within the container including baffles 402.

FIG. 4B shows a plurality of baffles according to an embodiment. FIG. 4B shows a plurality of baffles according to an embodiment. In FIG. 4B, a front view of the plurality of baffles is provided. Each of the baffles 412 has a trapezoidal profile, i.e. is trapezoidal in shape when viewed in the front view shown in FIG. 4B. A gap 414 is provided between each of the baffles 412 shown in FIG. 4B. The gap 414 can have a varying width along the height thereof due to the trapezoidal shape of the baffles 412. In an embodiment, the gap 414 is sized so as to promote drying of the container including the baffles 412 following washing, for example by having the gaps 414 each being at least one eighth of an inch (⅛″) in width where the baffles 412 meet the container shell portion they are attached to. In an embodiment, this spacing of the gaps is provided when all of the baffles 412 extend from the same container shell portion. In an embodiment where baffles 412 alternate extending from opposing container shell portions (for example, as described above and shown in FIG. 2), the gaps 414 between adjacent baffles 412 when the container is closed can be sized without respect to water trapping effects. For example, the gaps 414 between baffles 412 when the container is closed at least include portions where the gap 414 is smaller than one eighth of an inch (⅛″) in width. The width of the gaps 414 can be selected based on the desired flow characteristics within a container including the baffles 412. In an embodiment, the width of the gaps 414 can be varied along a length of a row of the baffles 412, for example varying based on a distance of the particular baffle 412 from a center line of the container, distance from a purge inlet, or any other suitable basis for selecting the sizing of gaps 414 so as to achieve desired flow conditions within the container including baffles 412.

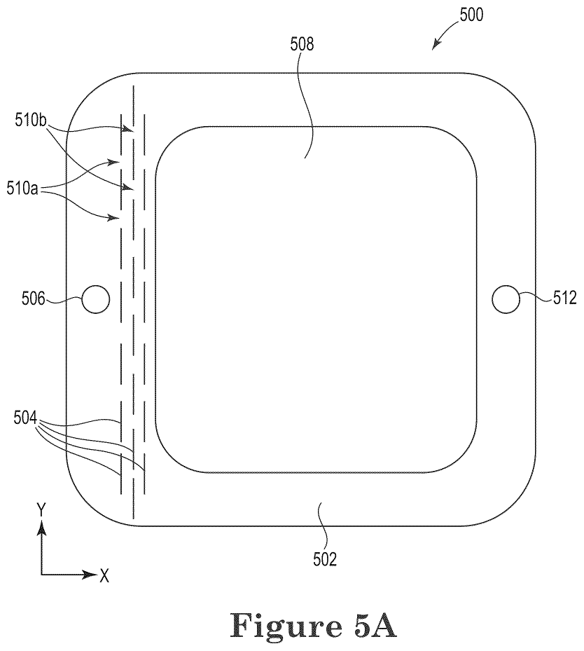

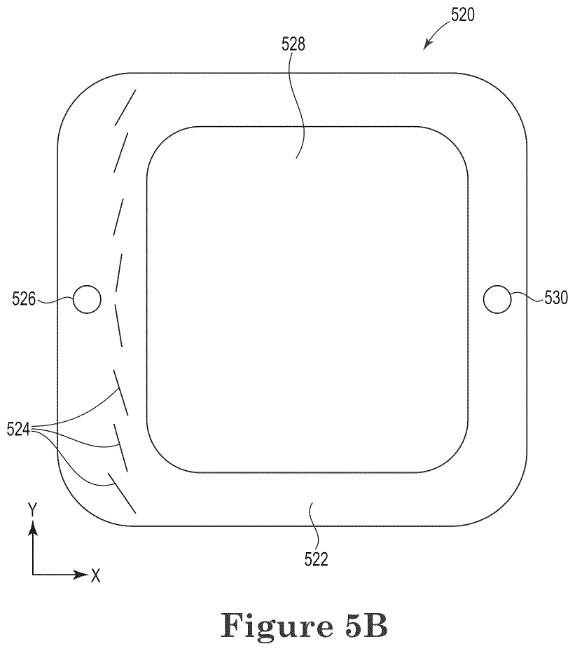

FIG. 5A shows a portion of a photolithography substrate container 500 according to an embodiment. In container shell portion 502, a plurality of baffles 504 are provided between purge inlet 506 and photolithography substrate accommodation region 508. As shown in FIG. 5A, the plurality of baffles are provided in a plurality of rows each extending across the container shell portion 502. The plurality of rows of the baffles 504 can be offset such that gaps 510a provided in a first row of baffles are not in alignment with gaps 510b provided in a second row of baffles, as defined with respect to horizontal axis direction X of the container shell portion 502. Photolithography substrate container 500 further includes purge outlet 512.

FIG. 5B shows a portion of a photolithography substrate container 520 according to an embodiment. In container shell portion 522, a plurality of baffles 524 are provided between purge inlet 526 and photolithography substrate accommodation region 528. As shown in FIG. 5B, at least some of the plurality of baffles are angled with respect to horizontal axis direction X of the container shell portion 522, with the angle being an angle other than parallel or perpendicular. In an embodiment, the various baffles 524 within the plurality of baffles 524 all are angled having the same angle with respect to horizontal axis direction X of the container shell portion 522. In an embodiment, the various baffles 524 within the plurality of baffles 524 can have differing angles with respect to horizontal axis direction X of the container shell portion 522. For example, the angles can vary based on the distance of the particular baffle 524 from a center line of the container shell portion 522, vary based on a distance of the particular baffle 524 from the purge inlet 526, or any other suitable basis for selecting the angle capable of achieving desired flow characteristics within the container including container shell portion 522. In an embodiment, the plurality of baffles 524 are oriented such that there is no angle with respect to the horizontal axis direction X of the container shell portion 522. Photolithography substrate container 520 further includes outlet 530.

### ASPECTS

It is understood that any of aspects 1-8 can be combined with any of aspects 9-16 or 17-20. It is understood that any of aspects 9-16 can be combined with any of aspects 17-20.

Aspect 1. A photolithography substrate container, comprising:
a first shell portion;
a purge inlet;
a purge outlet;
a second shell portion, the first shell portion and the second shell portion defining a photolithography substrate accommodation space configured to receive a photolithography substrate;
a plurality of baffles configured to be positioned between the purge inlet and the photolithography substrate accommodation space when the first shell portion and the second shell portion are closed together.

Aspect 2. The photolithography substrate container according to aspect 1, wherein at least some of the plurality of baffles are formed integrally with the first shell portion.

Aspect 3. The photolithography substrate container according to any of aspects 1-2, wherein at least some of the plurality of baffles are formed integrally with the second shell portion.

Aspect 4. The photolithography substrate container according to any of aspects 1-3, wherein at least some of the plurality of baffles are provided in an insert configured to be joined to at least one of the first shell portion and the second shell portion.

Aspect 5. The photolithography substrate container according to any of aspects 1-4, wherein the plurality of baffles are provided in a plurality of rows.

Aspect 6. The photolithography substrate container according to any of aspects 1-4, wherein the plurality of baffles are arranged in a single row.

Aspect 7. The photolithography substrate container according to any of aspects 1-6, wherein at least some baffles of the plurality of baffles have a rectangular profile.

Aspect 8. The photolithography substrate container according to any of aspects 1-7, wherein at least some baffles of the plurality of baffles have a trapezoidal profile.

Aspect 9. A pellicle container, comprising:
a first shell portion;
a purge inlet;
a purge outlet;
a second shell portion, the first shell portion and the second shell portion defining a pellicle accommodation space configured to receive a pellicle; and
a plurality of baffles configured to be positioned between the purge inlet and the pellicle accommodation space when the first shell portion and the second shell portion are closed together.

Aspect 10. The pellicle container according to aspect 9, wherein at least some of the plurality of baffles are formed integrally with the first shell portion.

Aspect 11. The pellicle container according to any of aspects 9-10, wherein at least some of the plurality of baffles are formed integrally with the second shell portion.

Aspect 12. The pellicle container according to any of aspects 9-11, wherein at least some of the plurality of baffles are provided in an insert configured to be joined to at least one of the first shell portion and the second shell portion.

Aspect 13. The pellicle container according to any of aspects 9-12, wherein the plurality of baffles are provided in a plurality of rows.

Aspect 14. The pellicle container according to any of aspects 9-12, wherein the plurality of baffles are arranged in a single row.

Aspect 15. The pellicle container according to any of aspects 9-14, wherein at least some baffles of the plurality of baffles have a rectangular profile.

Aspect 16. The pellicle container according to any of aspects 9-15, wherein at least some baffles of the plurality of baffles have a trapezoidal profile.

Aspect 17. A method of purging a pellicle container, comprising receiving a flow of a purge gas at a purge inlet of the pellicle container, directing the purge gas through a plurality of baffles into a pellicle accommodation space of the pellicle container, and directing the purge gas out of the pellicle container through a purge gas outlet of the pellicle container.

Aspect 18. The method according to aspect 17, further comprising attaching an insert including at least some of the plurality of baffles into the pellicle container.

Aspect 19. The method according to any of aspects 17-18, further comprising placing a pellicle into the pellicle accommodation space.

Aspect 20. The method according to any of aspects 17-19, further comprising cleaning the pellicle container using water and drying the pellicle container after the cleaning.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A photolithography substrate container, comprising:
a first shell portion;
a purge inlet;
a purge outlet;
a second shell portion, the first shell portion and the second shell portion defining a photolithography substrate accommodation space configured to receive a photolithography substrate; and
a plurality of baffles configured to be positioned between the purge inlet and the photolithography substrate accommodation space when the first shell portion and the second shell portion are closed together.

2. The photolithography substrate container of claim 1, wherein at least some of the plurality of baffles are formed integrally with the first shell portion.

3. The photolithography substrate container of claim 1, wherein at least some of the plurality of baffles are formed integrally with the second shell portion.

4. The photolithography substrate container of claim 1, wherein at least some of the plurality of baffles are provided in an insert configured to be joined to at least one of the first shell portion and the second shell portion.

5. The photolithography substrate container of claim 1, wherein the plurality of baffles are provided in a plurality of rows.

6. The photolithography substrate container of claim 1, wherein the plurality of baffles are arranged in a single row.

7. The photolithography substrate container of claim 1, wherein at least some baffles of the plurality of baffles have a rectangular profile.

8. The photolithography substrate container of claim 1, wherein at least some baffles of the plurality of baffles have a trapezoidal profile.

9. A pellicle container, comprising:
a first shell portion;
a purge inlet;
a purge outlet;
a second shell portion, the first shell portion and the second shell portion defining a pellicle accommodation space configured to receive a pellicle; and
a plurality of baffles configured to be positioned between the purge inlet and the pellicle accommodation space when the first shell portion and the second shell portion are closed together.

10. The pellicle container of claim 9, wherein at least some of the plurality of baffles are formed integrally with the first shell portion.

11. The pellicle container of claim 9, wherein at least some of the plurality of baffles are formed integrally with the second shell portion.

12. The pellicle container of claim 9, wherein at least some of the plurality of baffles are provided in an insert configured to be joined to at least one of the first shell portion and the second shell portion.

13. The pellicle container of claim 9, wherein the plurality of baffles are provided in a plurality of rows.

14. The pellicle container of claim 9, wherein the plurality of baffles are arranged in a single row.

15. The pellicle container of claim 9, wherein at least some baffles of the plurality of baffles have a rectangular profile.

16. The pellicle container of claim 9, wherein at least some baffles of the plurality of baffles have a trapezoidal profile.

17. A method of purging a pellicle container, comprising receiving a flow of a purge gas at a purge inlet of the pellicle container, directing the purge gas through a plurality of baffles into a pellicle accommodation space of the pellicle container, and directing the purge gas out of the pellicle container through a purge gas outlet of the pellicle container.

18. The method of claim 17, further comprising attaching an insert including at least some of the plurality of baffles into the pellicle container.

19. The method of claim 17, further comprising placing a pellicle into the pellicle accommodation space.

20. The method of claim 17, further comprising cleaning the pellicle container using water and drying the pellicle container after the cleaning.
